(19) United States
(12) Patent Application Publication
(10) Pub. No.: US 2024/0395619 A1
(43) Pub. Date: Nov. 28, 2024

(54) SEMICONDUCTOR DEVICE HAVING THROUGH VIA AND METHOD OF FABRICATING THEREOF

(71) Applicant: Taiwan Semiconductor Manufacturing Company, Ltd., Hsinchu (TW)

(72) Inventors: Li-Yu LEE, New Taipei City (TW); Cheng-Hao YEH, Taichung City (TW); Liang-Wei WANG, Hsinchu City (TW); Dian-Hau CHEN, Hsinchu (TW)

(21) Appl. No.: 18/323,225

(22) Filed: May 24, 2023

(51) Int. Cl. H01L 21/768; H01L 23/48

(52) U.S. Cl. CPC H01L 21/76898; H01L 23/481

(57) ABSTRACT

Semiconductor structures and methods for forming the same that include a through substrate via. Sacrificial semiconductor structures (e.g., fins) are formed with metal gate structures in a through via region. An opening is formed through BEOL layers to expose the metal gates, which may then be removed. A liner layer is formed on sidewalls of the opening including on semiconductor structures extending from the substrate. The opening is then extended into the substrate and a through substrate via is formed from the extended opening.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

More recent attempts have focused on through vias, e.g., through-silicon or through-substrate vias (TSVs). TSVs have found applications in three-dimensional (3D) ICs for routing electrical signal from one side of a silicon substrate of an IC to the other side thereof. Generally, a TSV is formed by etching a vertical via opening through a substrate and filling the via opening with a conductive material. While existing TSV structures and methods of fabricating thereof are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the variFI.ous features may be arbitrarily increased or reduced for clarity of discussion.

FIG. 1 is a flow chart illustrating an embodiment of a method of forming a device structure and a via structure through the device structure, according to various aspects of the present disclosure.

FIGS. 2A, 3, 4A, 4B, 5, 6, 7, 8, 9, 10, 11A, 11B, 12, 13, 14, 15, 16, 17A, and 17B are fragmentary cross-sectional views of a workpiece undergoing operations of the method in FIG. 1, according to various aspects of the present disclosure.

FIGS. 2B and 2C are top views of a device, according to various aspects of the present disclosure.

### DETAILED DESCRIPTION

The present disclosure relates generally to integrated circuit devices, and more particularly, to interconnect structures for integrated circuit devices.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

An interconnect structure electrically couples various components (for example, transistors, resistors, capacitors, and/or inductors) fabricated on a substrate, such that the various components can operate as specified by design requirements. An interconnect structure includes a combination of dielectric layers and conductive layers configured to provide electrical signal routing. The conductive layers include via and contact features that provide vertical connections and conductive lines that provide horizontal connections. In some implementations, an interconnect structure may have multiple metal layers (or metallization layers) that are vertically interconnected by via or contact features, and can be referred to as a multi-layer interconnect (MLI) structure. During operation of the IC device, the interconnect structure routes signals among the components of the IC device and/or distribute signals (for example, clock signals, voltage signals, and/or ground signals) to the components. An interconnect structure is formed in a back-end-of-the-line (BEOL) process, typically formed after the front-end-of-the-line (FEOL) process forms the active devices such as a transistor on a substrate and the middle-end-of-the-line (MEOL) process forms contacts to the active devices, such as conductive plugs to source/drain regions and gate structures.

In some implementations, there is a need to provide a vertical interconnect that extends through the interconnect structure and/or the substrate to facilitate various device structures, such as CMOS image sensors (CISs), a three-dimensional integrated circuit (3DIC), MEMS devices, radio frequency (RF) devices, wafer-on-wafer (WoW) devices, and so on. Such a vertical interconnect may be referred to as a through via, or a through-silicon or through-substrate via (TSV) as it extends through, in whole or in part, the semiconductor substrate. The term through via or TSV in the present disclosure broadly encompasses via structures that provide direct signal routing from a frontside of the substrate and a backside of the substrate or vice versa. The TSV may extend vertically through not only the silicon substrate, but the BEOL, MEOL, and/or FEOL regions of the device.

The through via (TSV), and the regions that the through via are formed within, typically span relatively large areas of the substrate. In some implementations, through vias are larger than active devices (e.g., transistors formed in the FEOL processes) of the device. Thus, regions of through vias may have vastly different pattern densities than the active device regions. Leaving a larger region vacant for receiving the through via when forming the active semiconductor features (e.g., when forming FEOL, MEOL or BEOL structures) can cause processing challenges. For example, due the pattern density differences, inconsistent processing can occur in the through via region. In an embodiment, dishing can occur in the through via region during processes such as chemical mechanical polishing (CMP) processes.

Through vias may be formed after many layers of a BEOL process have been formed, which in turn are formed over and after FEOL and MEOL processes. The present disclosure provides a method and semiconductor structure forms sacrificial features in the through via region during the FEOL processes, thereby improving pattern uniformity across the die. And, thus, processing challenges may be mitigated, such as reduction in dishing. In some embodiments, the FEOL processes include forming active device features such as active regions comprising semiconductor structures extending from the substrate (e.g., fins or crown structures) and transistor features such as metal gates and source/drain regions in the through via region, concurrently with formation of active transistor devices. In other words, in some implementations, active regions are provided extending from the substrate such as fin structures including crown structures. Metal gates are formed through replacement gate processes not only in the device regions, but in the through via region and source/drain regions are grown on the active regions not only in the device regions, but also in the through via regions. After forming the FEOL features, MEOL structures such as contacts and surrounding dielectric layers are formed. And then the BEOL features, such as MLI structures including their surrounding dielectric layers are formed. Thereafter the via for the through via is formed, in some implementations, with liner materials that protect adjacent structures.

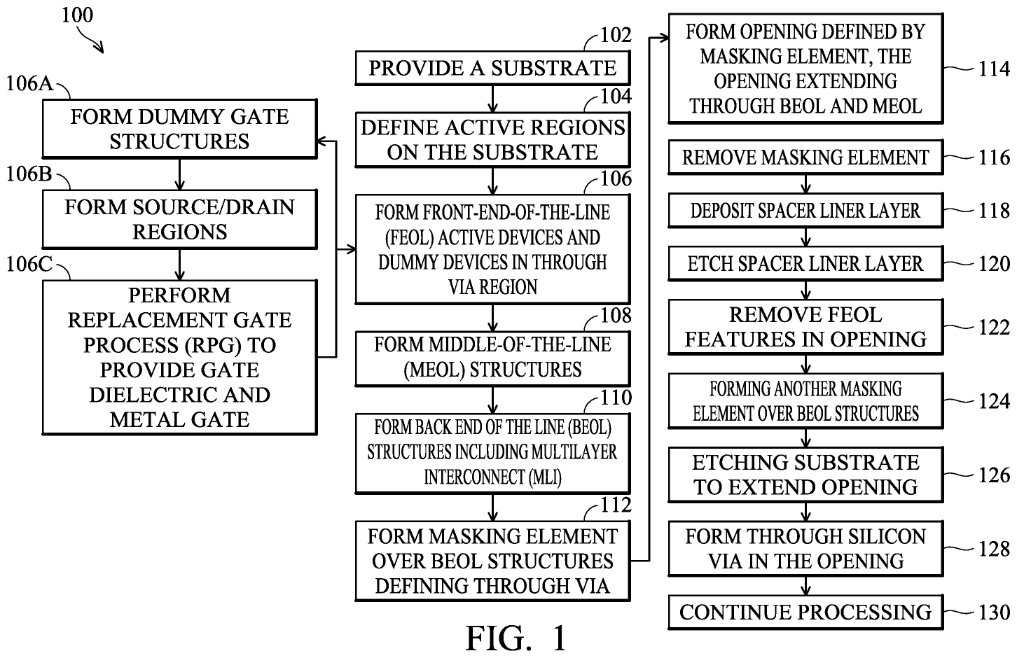

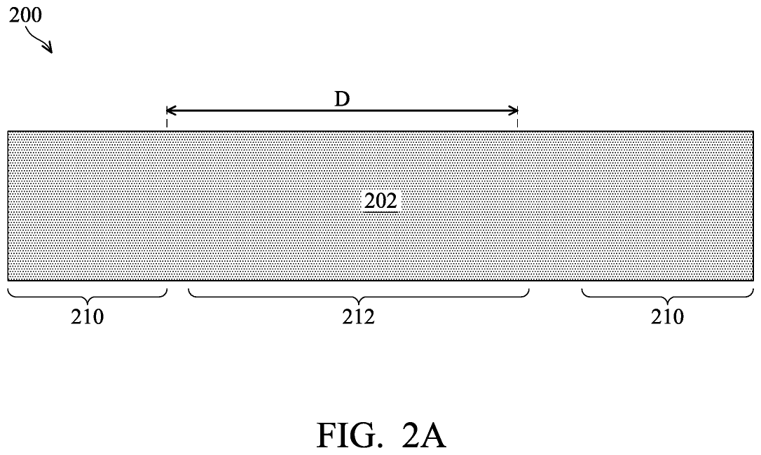

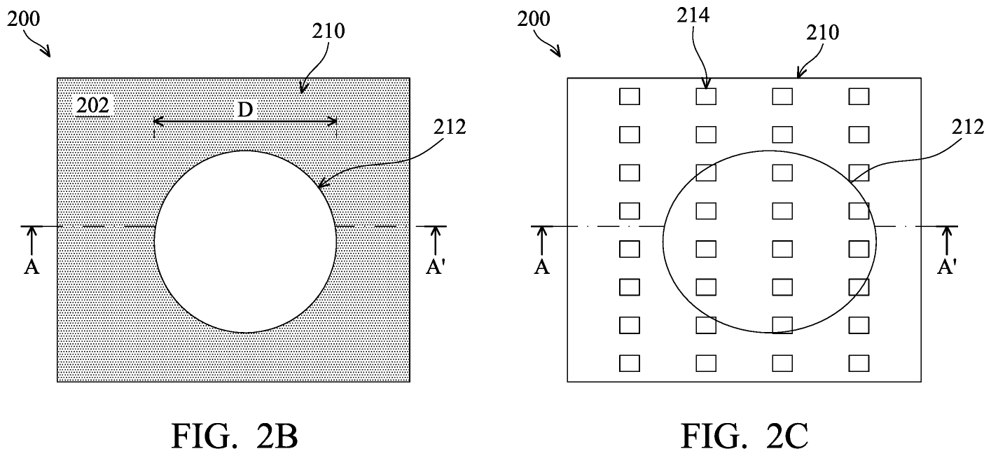

The various aspects of the present disclosure will now be described in more detail with reference to the figures. In that regard, FIG. 1 is a flowchart illustrating a method 100 of forming a device structure exemplified by a device 200 (shown in FIGS. 2A-17B) including a through via structure, according to various aspects of the present disclosure. The method 100 is merely an example and is not intended to limit the present disclosure to what is explicitly illustrated in the method 100. Additional steps can be provided before, during and after the method 100, and some steps described can be replaced, eliminated, or moved around for additional embodiments of the method. Not all steps are described herein in detail for reasons of simplicity. The method 100 is described below in conjunction with FIGS. 2A-17B, which are fragmentary cross-sectional views and top views of the device 200 at different stages of fabrication according to various embodiments of the method 100. Throughout the present disclosure, unless expressly otherwise described, like reference numerals denote like features.

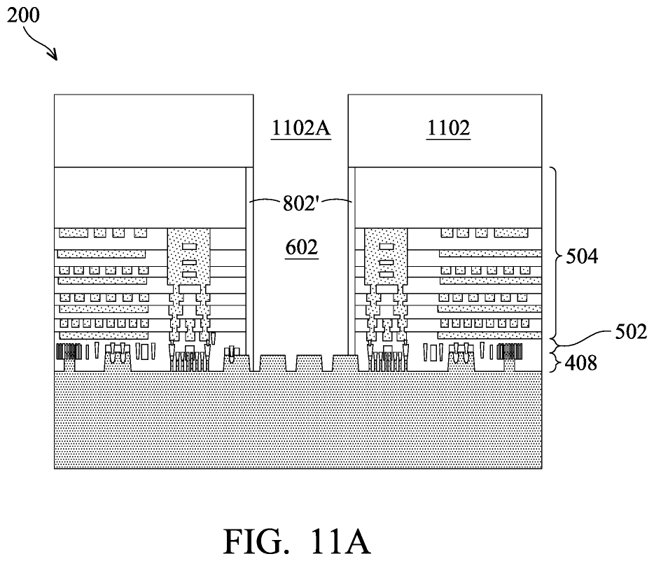

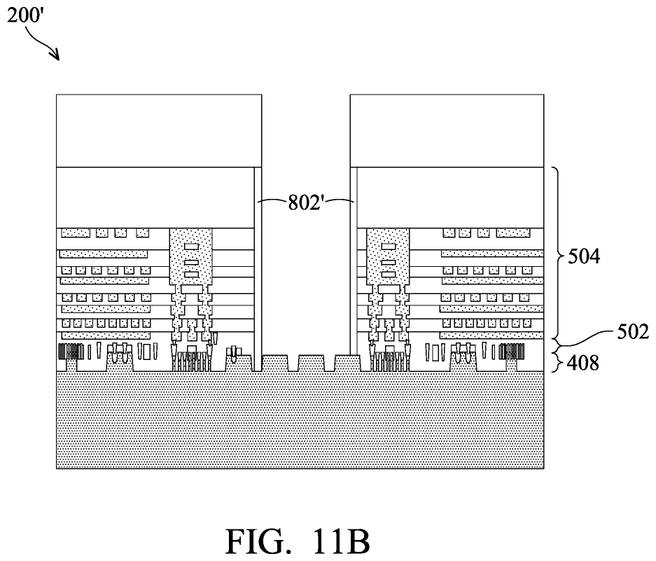

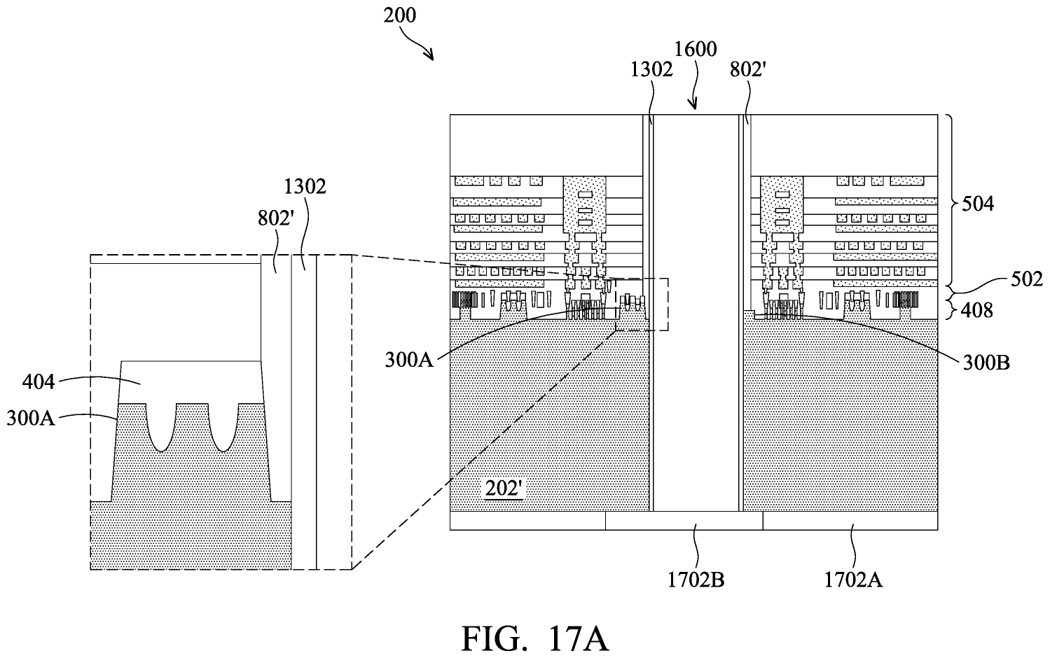

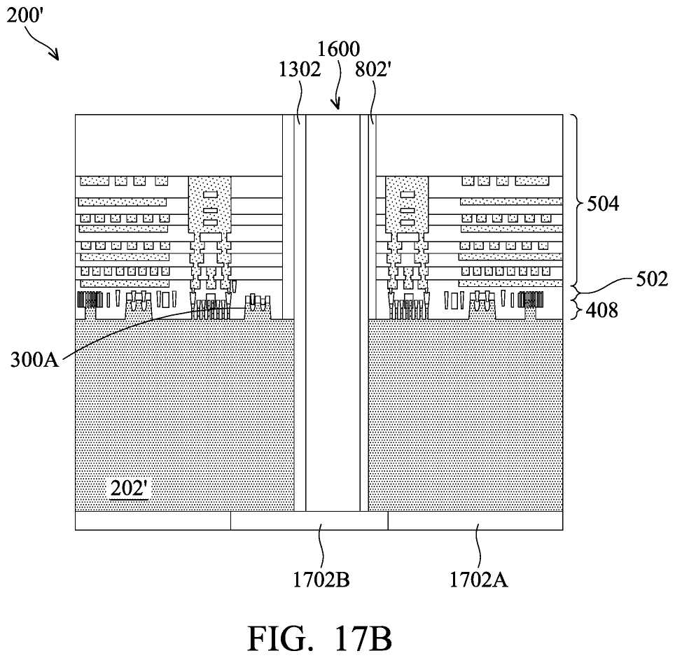

The device 200 shown in the figures of the present disclosure is simplified and not all features in the device 200 are illustrated or described in detail. The device 200 shown in the figures may be a portion of an IC chip, a system on chip (SoC), or portion thereof, that may include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some implementations, the device 200 and the formed through via is interconnected with another device, such as another device 200, for example in a stacked formation. FIGS. 11B and 17B illustrate a device 200′, which is substantially similar to the device 200 with another exemplary placement of the through via with respect to the adjacent FEOL structures.

Referring to FIGS. 1 and 2A, 2B, 2C, the method 100 includes a block 102 where a substrate 202 is provided. The substrate 202 is a part of the device 200, which will include further structures as the method 100 progresses. In an embodiment, the substrate 202 includes silicon (Si). Alternatively or additionally, the substrate 202 may include another elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 202 may be a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. The substrate 202 can include various doped regions (not shown) depending on design requirements of the device 200. In some implementations, the substrate 202 includes p-type doped regions (for example, p-type wells) doped with p-type dopants, such as boron (for example, BF₂), indium, other p-type dopant, or combinations thereof. In some implementations, the substrate 202 includes n-type doped regions (for example, n-type wells) doped with n-type dopants, such as phosphorus (P), arsenic (As), other n-type dopant, or combinations thereof. In some implementations, the substrate 202 includes doped regions formed with a combination of p-type dopants and n-type dopants. The various doped regions can be formed directly on and/or in the substrate 202, for example, providing a p-well structure, an n-well structure, a dual-well structure, a raised structure, or combinations thereof. An ion implantation process, a diffusion process, and/or other suitable doping process can be performed to form the various doped regions.

The method 100 includes a block 104 where active regions are formed on the substrate 202 in an FEOL process. The active regions may be semiconductor structures that extend vertically (e.g., in the z-direction) from a substrate. In some implementations, the active regions are formed in fin-like regions such as provided when forming fin-type field effect transistors (FinFETs). In some implementations, the active regions are formed in a crown structure. The crown structure may include fin-type structures extending above a base portion of the crown structure, which together form a semiconductor structure that extends above an upper surface of the substrate. In some other implementations, the semiconductor structures and/or active regions are designed to form other multi-gate devices such as gate-all-around (GAA) transistors. A GAA transistor has a gate structure that can extend, partially or fully, around a channel region to provide access to the channel region on two or more sides. The channel regions may include nanowire, nanosheets, or other shaped nano-structures. In some implementations, the active regions are planar such as formed in the formation of planar transistors. Between active regions, there may be isolation regions such as shallow trench isolation (STI) features, extending between active regions (e.g., crowns or planar regions). See isolation structures 400.

In some implementations, crown structure having fins-referred to generally as a semiconductor structure—may be formed by directly patterning a top portion of the substrate 202, such that the structures protrude from the substrate 202. The semiconductor structure may also be formed by epitaxially growing semiconductor layer(s) on the substrate and then patterning the layer(s) to form the individual semiconductor structures. The semiconductor structure may be patterned by any suitable method. For example, the semiconductor structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins by etching the initial epitaxial semiconductor layers.

In some implementations, certain regions of the substrate 202 are designated to be regions for device formation including front-end-of-the-line (FEOL) active devices such as transistors, capacitors, memory structures, passive devices, and/or other suitable structures. These areas are referred to as device areas, illustrated as device region 210 in FIGS. 2A, 2B, 2C. The device region 210 include active regions and surrounding insulating regions (e.g., isolation structures such as STI) disposed between active regions. Other regions of the substrate 202 are designated to be regions for through via formation (also referred to as through-substrate vias (TSV)), illustrated as through via region 212 in FIGS. 2A, 2B, 2C. In some implementations, the through via region 212 has a dimension of at least D. In some embodiment, the dimension D is for example, 5 microns (μm) or greater. In an embodiment, the through via region 212 has a D of approximately 6 μm. In an embodiment, the through via region 212 has a D of between approximately 5 μm and 10 μm. It is noted there are a plurality of through via regions 212 and device regions 210 per substrate 202. The dimension D may be measured in any and/or all of the directions of the through via region 212 in the top view. The dimension D may be significantly larger (e.g., 5 times or more) than that of the size of a FEOL device. As illustrated in FIG. 2C, a plurality of FEOL devices (e.g., transistors) 214 may be formed in the device region 210. These may form active transistors of a resultant device 200. In the present disclosure, the FEOL devices (e.g., transistors) 214 are also formed throughout the via regions 212 (where they are subsequently removed as discussed below).

In some implementations, the through via region 212 is approximately circular in a top view as illustrated in FIGS. 2B, 2C. In some implementations, the through via region 212 is of oval shape in a top view where at least one dimension is D as described above. In some implementations, the through via region 212 is of a rectangular shape (including square) from a top view where at least one dimension is D as described above. These shapes are exemplary only and other shapes are possible including, for example, an octagonal shape. In some embodiments, the through via region 212 is defined to be the same shape as the through via or TSV subsequently formed. In other embodiments, the through via region 212 may be of a different shape than the TSV subsequently formed. In each case, the through via region 212 encases the TSV to be formed. In other words, the through via region 212 is at least as large as the TSV. In some implementations, regions surrounding the TSV are included in the TSV region and include, for example, dummy device, dummy features (e.g., semiconductor structures, gates, s/d) or portions thereof.

While illustrated on a substrate 202, the through via region 212 and the device region 210 may also be defined in the design data associated with the device 200. In an embodiment, the through via region 212 and the device region 210 are defined in the layout data associated with the device 200. The layout data may follow design rule checker (DRC) software or data that define the through via region in a manner that does not allow placement of active devices of the device 200 in said region. The layout defining the device region 210 and the through via region 212 may be defined in a layout database such as GDS, GDSII, OASIS, and/or other suitable layout formats.

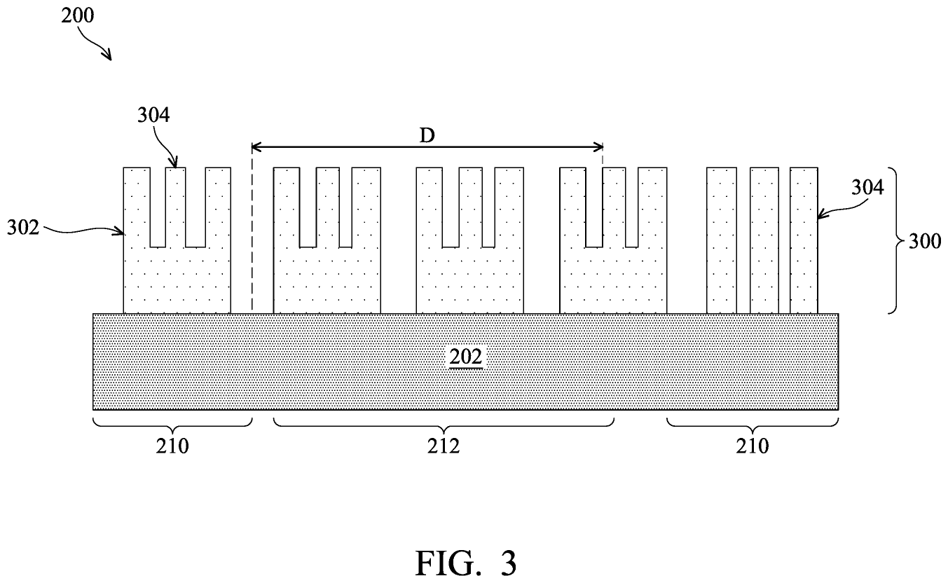

Referring to the example of FIG. 3, semiconductor structures 300 are formed on which a device will be formed. The semiconductor structures 300 provide an active region such as where a channel of a transistor is to be formed. In an embodiment, the semiconductor structures 300 are crown structures having a base 302 and fin-like structures 304 extending from the crown structure base portion 302. As illustrated in FIG. 3, some semiconductor structures 300 defining the active region are fins 304 extending from the substrate 202 (without a crown structure). The semiconductor structures 300 are formed in the device region 210 and the through via region 212 of the substrate 202. The semiconductor structures 300 in the through via region 212 may be referred to as dummy semiconductor structures, or dummy active regions, as the structures are subsequently removed from the device 200.

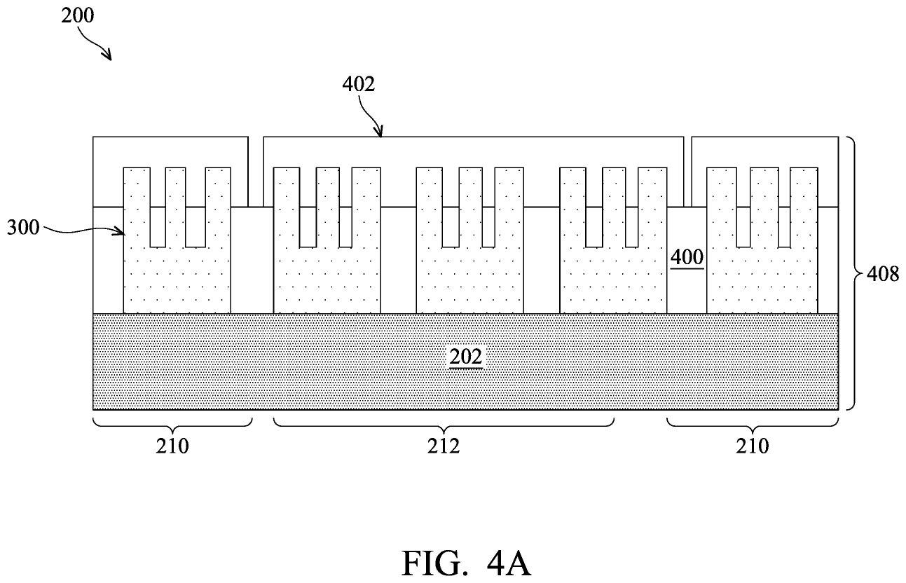

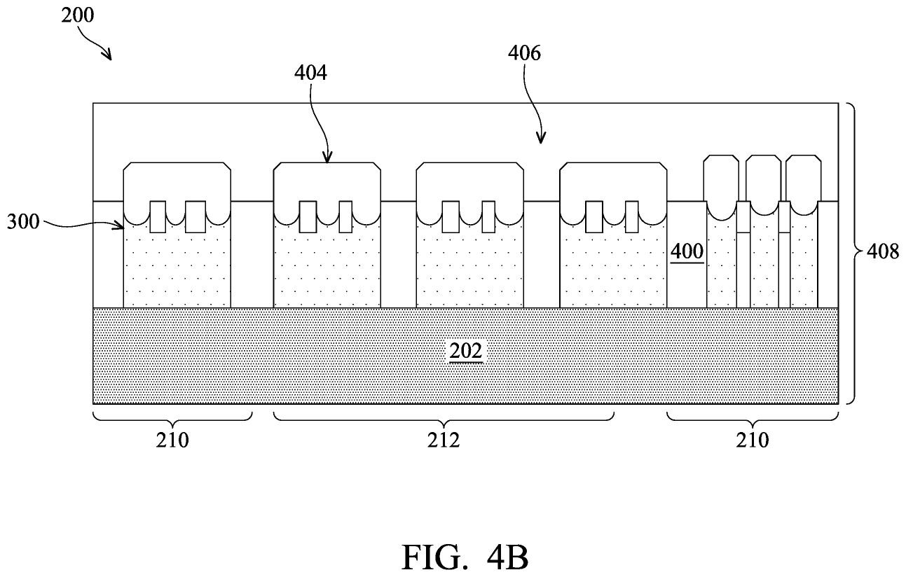

Between the active regions, semiconductor structures 300, isolation features are formed. In some implementations, the isolation features are shallow trench isolation (STI) features. Referring to FIGS. 4A, 4B, isolation features 400 are illustrated extending between semiconductor structures 300. Isolation features 400 include silicon oxide, silicon nitride, silicon oxynitride, other suitable isolation material (for example, including silicon, oxygen, nitrogen, carbon, or other suitable isolation constituent), or combinations thereof. Isolation feature 400 can be configured as a shallow trench isolation (STI) structure, a deep trench isolation (DTI) structure, and/or local oxidation of silicon (LOCOS) structure. For example, isolation feature 400 may be an STI feature that defines and electrically isolates semiconductor structures 300 from each other. And in some implementations, the isolation feature 400 includes isolation material isolating portions of the fins 304 on the crown structure 302. The STI feature can be formed by etching a trench in substrate 202 (for example, by using a dry etching process and/or a wet etching process) and filling the trench with insulator material (for example, using a chemical vapor deposition (CVD) process or a spin-on glass process). A chemical mechanical polishing (CMP) process may be performed to remove excess insulator material and/or planarize the top surface of isolation feature 400. The insulator material may then be etched back to form the semiconductor structure 300 raising a height above the isolation feature 400. In another example, the isolation feature can be formed by depositing an insulator material over substrate 202 after forming the semiconductor structure 300 (in some embodiments, such that the insulator material layer fills gaps (trenches) between fins 304 on the crown semiconductor structure 302) and etching back the insulator material layer to form isolation feature 400. In some embodiments, the isolation feature includes a multi-layer structure that fills the trenches, such as a silicon nitride layer disposed over a thermal oxide liner layer. In another example, the isolation feature 400 includes a dielectric layer disposed over a doped liner layer (including, for example, boron silicate glass (BSG) or phosphosilicate glass (PSG)). In yet another example, the isolation feature includes a bulk dielectric layer disposed over a liner dielectric layer, where the bulk dielectric layer and the liner dielectric layer include materials depending on design requirements of the device 200.

The method 100 includes a block 106 where front-end-of-the-line (FEOL) devices are formed in the device region and in the through via region of the substrate. In some implementations, the FEOL devices include transistors comprised of FEOL features such as source/drain regions and/or gate structures. These FEOL devices are also referred to as active FEOL devices as they form the functionality of the device 200. Concurrently with the formation of active FEOL active devices in the device region, sacrificial FEOL devices commensurate in structure with the active FEOL devices, may be formed in a through via region 212 of the substrate. As discussed in the steps of the method 100 below, these sacrificial FEOL devices may be subsequently removed.

The active and sacrificial FEOL devices may be formed by various steps including, in an example, those illustrated in sub-step 106A, sub-step 106B, and sub-step 106C. These steps are exemplary only and not intended to be limiting. Other methods may be used to form the FEOL devices. The FEOL devices formed, active FEOL devices and/or sacrificial FEOL devices may be features of GAA devices, FinFET devices, CFET devices, planar transistors, and/or other device structures.

In an embodiment, block 106 begins at sub-step 106A where dummy gate structures are formed in the device region and the through via region. The dummy gate structures are formed in both the device region 210 and the through via region 212. In some implementations, the gate structures are formed in the device region 210 and the through via region 212 in substantially the same pattern density. See FIG. 2C. That is, in an embodiment, the pitch of the gate structures in the device region 210 is the same as the pitch of the gate structures in the through via region 212.

The dummy gate structures may be polysilicon and thus referred to as a poly gate (PG). The dummy gate structures are formed by suitable patterning and etching to form a dummy gate structure having sidewalls. The dummy gate structures may be configured substantially as illustrated in FIG. 4A and the illustration of the gate structures 402. On the sidewalls of the gate structures 402, spacer elements, also referred to simply as spacers (not shown). In some embodiments, the spacers are composed of silicon dioxide (SiO₂), silicon oxynitride (SiₓO_{y}N_{z}), composite (SiO₂/Si₃N₄), silicon nitride (Si₃N₄), and/or other suitable dielectrics.

Block 106 continues to sub-step 106B where source/drain features are formed adjacent the dummy gate structures (and spacer elements). The source/drain features may be formed in the device region 210 and the through via region 212. In an embodiment, the source/drain features are epitaxially grown from the semiconductor structures 300 and/or recesses within the semiconductor structures 300 adjacent the dummy gate structures. Referring to the example of FIG. 4B, a cross-sectional view through the semiconductor structures 300 illustrate source/drain regions 404.

The source/drain features 404 may be deposited using vapor-phase epitaxy (VPE), ultra-high vacuum CVD (UHV-CVD), molecular beam epitaxy (MBE), and/or other suitable processes. When a source/drain feature is n-type, it may include silicon (Si) doped with an n-type dopant, such as phosphorus (P) or arsenic (As). When a source/drain feature is p-type, it may include silicon germanium (SiGe) doped with a p-type dopant, such as boron (B) or boron difluoride (BF₂). In some embodiments, the source/drain features may include multiple layers such as layers with different dopant concentrations. In some implementations, the semiconductor structure 300 such as the fin 304 may be recessed to form openings, and the source/drain features 404 may be grown on the recessed structures.

Block 106 continues to sub-step 106C where a replacement gate (RPG) process is performed. The RPG process replaces the dummy gate structure (e.g., PG) discussed with reference to sub-step 106A with a functional gate structure such as a metal gate. It is noted that other methods of forming a gate structure may be provided in block 106, including other processes such as a gate-first process and the sub-steps 106A, 106B, and 106C are but an exemplary embodiment. The RPG process or other process of forming functional gates is performed on both the dummy gate structures of the device region 210 as well as the through via region 212.

In some implementations, after forming the dummy poly gate and spacers, the RPG process includes an inter-layer dielectric (ILD) layer that may be formed adjacent the dummy gate structures. The ILD layer may be deposited using PECVD, FCVD, spin-on coating, or a suitable deposition technique. A contact etch stop layer (CESL) may be deposited before the ILD layer is deposited such that the CESL is disposed between the ILD layer and the source/drain features 404. The CESL may include silicon nitride or silicon oxynitride and may be deposited using CVD, ALD, or a suitable method.

After depositing the ILD layer, a planarization process is performed to expose a top surface of the dummy gate in the RPG process. The planarization process may include CMP process. In some implementations, because of the semiconductor structures 300, fins 304, and/or dummy gate structures presence in the through via region 212, dishing of an ILD layer in the through via region 212 may be avoided during the CMP process. Referring to the example of FIG. 4B, an ILD layer 406 may be deposited. A substantially planar surface of the ILD layer 406 from device region 210 across through via region 212 to device region 210 may be provided. After planarization, the dummy gate (e.g., polysilicon) is then removed to form a trench within a replacement gate is formed as discussed above. FIG. 4A illustrates the replacement gate, which is configurated substantially as the dummy gate structure, in gate structure 402. The gate structures 402 are disposed in both the device regions 210 and the through via region 212. In an embodiment, the gate structures 402 include a metal electrode and thus, are referred to as metal gates.

The gate structures 402 may include an interfacial layer interfacing the semiconductor structure 300 such as the fin 304, a gate dielectric layer over the interfacial layer, and a gate electrode layer over the gate dielectric layer. The interfacial layer of the gate structures 402 may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer of the gate structures 402 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods. The gate electrode layer of the gate structures 402 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

The gate structures 402 and source/drain regions 404 are part of front-end-of-the-line (FEOL) structures formed in a FEOL layer 408. For example, these features form transistors such as devices (e.g., transistor) 214 of FIG. 2C. The FEOL layer 408 may also include portions of the semiconductor structures 300 and diffusion regions in the substrate such as discussed above, and isolation structure 400.

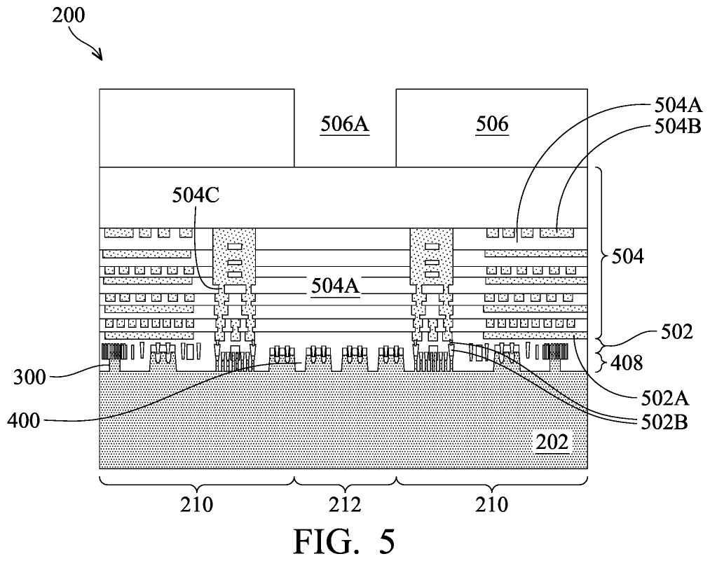

The method 100 includes a block 108 where middle end of the line (MEOL) structures are formed in an MEOL layer. The structures of the MEOL layer may include local interconnect structures and/or plugs providing connection to elements of the FEOL structures such as source/drain contact plugs to source/drain regions of a transistor or gate contact plugs to gate structures of a transistor. Referring to the example of FIG. 5, a MEOL layer 502 is formed over the substrate 202. The MEOL layer 502 includes an ILD layer 502A and contact plugs 502B. In an embodiment, the MEOL layer 502 includes gate contact plugs and source/drain contact plugs extending through the ILD layer 502A and/or the ILD layer 406. A gate contact 502B extends through the ILD layer 502A to be physically and electrically coupled to one of the gate structures 402. A source/drain contact plug 502B extends through the ILD layer 502A (and/or ILD layer 406) to be physically and electrically coupled to one of the source/drain features 404. In some embodiments, the ILD layer 502A may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), and/or other suitable dielectric materials.

The contacts 502B may include ruthenium (Ru), cobalt (Co), nickel (Ni), tungsten (W), copper (Cu), or other metals, as examples. In some embodiments, the contacts 502B may include a barrier layer to interface the ILD layer 502A. Such a barrier layer may include a metal nitride, such as titanium nitride, tantalum nitride, tungsten nitride, cobalt nitride, or nickel nitride. Additionally, in order to reduce contact resistance, a silicide feature may be disposed between the contact 502B and the transistor feature, such as gate 402. The silicide feature may include titanium silicide. The contact 502B may be deposited using CVD, PVD, or a suitable method. The formation of the MEOL layer 502 may conclude with a planarization process.

The method 100 includes a block 110 where a back end of the line (BEOL) layer including BEOL features is formed. The BEOL layer include a multi-layer interconnect (MLI) providing interconnections using metal lines or vias extending through dielectric layers. Referring to the example of FIG. 5, BEOL processes form a BEOL layer 504 including a stack of metallization layers and interposing dielectrics, also referred to as MLI structure 504. The MLI structure 504 may include a plurality of metallization layers 504B such as eight (8) to thirteen (13) metallization layers, denoted as metallization layers M1-Mn. These metallization layers 504B typically provide horizontal routing. Vias 504C provide vertical routing connecting the metallization layers 504B. Generally, the metallization layers M1-Mn comprise layers of conductive wiring comprising conductive lines (e.g., metallization layers 504B extending laterally) and vias (e.g., vias 504C extending vertically between metal lines) to electrically couple to the MEOL structures 502, such as the contacts 502B. The layers of conductive wiring are formed in layers of a dielectric material, such as inter-metal dielectric (IMD) layers 504A. The IMD layers 504A may comprise a low dielectric constant or an extreme low dielectric constant (ELK) material, such as an oxide, SiO₂, borophosphosilicate glass (BPSG), TEOS, spin on glass (SOG), undoped silicate glass (USG), fluorinated silicate glass (FSG), high-density plasma (HDP) oxide, or plasma-enhanced TEOS (PETEOS). A planarization process, such as a CMP process, may be performed to planarize each of the IMD layers 504A.

The metallization layers including metallization layers 504B and vias 504C may be formed, for example, using a plating and etching process or through a damascene or dual-damascene process, in which openings are etched into the corresponding dielectric layer (IMD layer) and the openings are filled with a conductive material. The metallization layers 504B may be formed of any suitable conductive material, such as a highly-conductive metal, low-resistive metal, elemental metal, transition metal, or the like. In an embodiment the metallization layers 504B may be formed of copper, although other materials, such as tungsten, aluminum, gold, or the like, could alternatively be utilized. In an embodiment in which the metallization layers 504B are formed of copper, the metallization layers 504B may be deposited by electroplating techniques.

The metallization layers 504B and/or vias 504C may include a liner and/or a barrier layer. For example, a liner (not shown) may be formed over the dielectric layer in the openings, the liner covering the sidewalls and bottom of the opening. The liner may be either tetraethylorthosilicate (TEOS) or silicon nitride, although any suitable dielectric may alternatively be used. The liner may be formed using a plasma enhanced chemical vapor deposition (PECVD) process, although other suitable processes, such as physical vapor deposition or a thermal process, may alternatively be used. The barrier layer may be formed over the liner (if present) and covering the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), combinations of these, or the like. The barrier layer may comprise tantalum nitride, although other materials, such as tantalum, titanium, titanium nitride, combinations of these, and the like may alternatively be used.

It is noted the MEOL 502 and the BEOL 504 are formed through the through via region 212. However, MEOL 502 and/or BEOL 504 in the through via region 212 include dielectric layers, ILD 502A and IMD 504A, respectively. In an embodiment, the MEOL layer 502 and/or BEOL layer 504 in the through via region 212 do not include metallization layers. For example, contacts 502B are omitted from the MEOL 502 in the through via region 212. And in some implementations, metallization layers 504B and vias 504C are omitted in the through via region 212. In some implementations, MEOL layer 502 conductive features are formed in the via region 212, but the BEOL layer 504 metallization features are not.

The method 100 includes block 112 where a masking element is formed over the substrate (over the BEOL layer) to define the through via location. Referring to the example of FIG. 5, a masking element 506 having an opening 506A defining the through via location is formed over the BEOL layer 504. The masking element 506 may be a photoresist. In some implementations, the masking element 506 may also include a hard mask layer. In some implementations, the opening 506A has a dimension of approximately D, as discussed above. The masking element 506 may be patterned using suitable photolithography and etching processes.

The masking layer 506 may include photoresist, silicon oxide, silicon nitride, silicon carbide, aluminum oxide, titanium nitride, or other suitable materials. The deposited masking layer then undergoes a pre-exposure baking process, exposure to radiation reflected from or transmitted through a photomask, a post-exposure baking process, and developing process, so as to form a patterned masking layer with an opening 506B aligning with to-be formed opening for the through via discussed below.

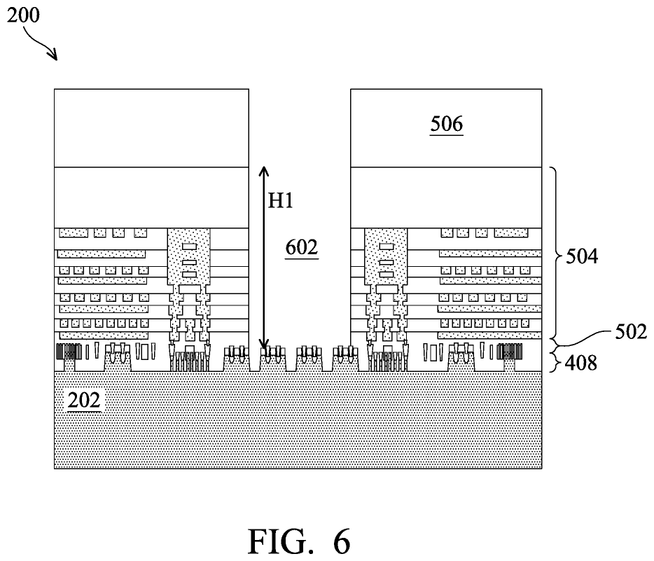

The method 100 includes block 114 where a via opening is etched in the BEOL layer and the MEOL layer of the device as defined by the masking element of block 114. Referring to the example of FIG. 6, an opening 602 is etched extending through the BEOL layer 504 and MEOL layer 502. In some implementations, the isolation region 400 between the semiconductor structures 300 may also be removed in the etching. That is, as the etching is targeting dielectric materials of the BEOL layer 504 and the MEOL layer 502, the exposed isolation feature 400 is also removed. FEOL layer 408 features including semiconductor structures 300, the gate structures 402 and source/drain features 404 formed thereon are exposed in the opening 602. The opening 602 may be formed by suitable etching processes. The etching process(es) can include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃). and/or acetic acid (CH₃COOH); or other suitable wet etchant. In some embodiments, a plurality of etching processes are performed. In an embodiment, the etching of the opening 602 is an oxide targeting etch.

In some implementations, the opening 602 is approximately circular in a top view. In some implementations, the opening 602 is of oval shape. In some implementations, the opening 602 is of a rectangular shape (including square) from a top view. These shapes are exemplary only and other shapes are possible including, for example, an octagonal shape. In some embodiments, the opening 602 is approximately the same shape and/or size as the through via region 212 discussed above. In an embodiment, the height H1 of the opening 602 is between approximately 1.5 microns and 3 microns. In an embodiment, the height H1 is approximately 2 μm.

It is noted that two semiconductor structures 300 are exposed in the opening 602 in FIG. 6. This is exemplary only and not intended to be limiting beyond what is claimed. Any number of semiconductor structures 300 may be exposed in the opening 602. It is also noted that the opening 602 exposes a sidewall of a semiconductor structure 300 as illustrated in FIG. 6 (left), however, this is also exemplary and other alignments of the opening 602 sidewall may be implemented. Similarly, as illustrated in FIG. 6, the opening 602 has an opposing sidewall interfaces a midpoint of semiconductor structure 302, this is also exemplary only and other alignments of the opening 602 may be implemented.

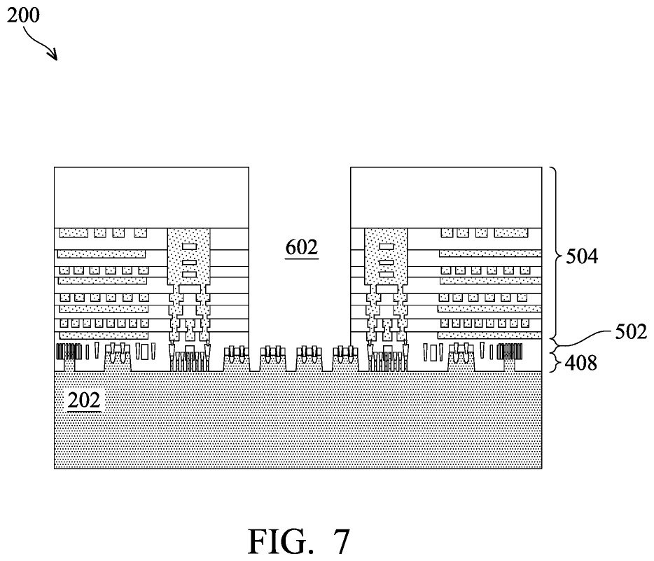

The method 100 includes block 116 where the masking element is removed. Referring to the example of FIG. 7, the masking element 506 (FIG. 6) is removed. In some implementations, the masking element 506 may be removed by a suitable process such as ashing. In some implementations, the ashing may be followed by a wet etch/clean process.

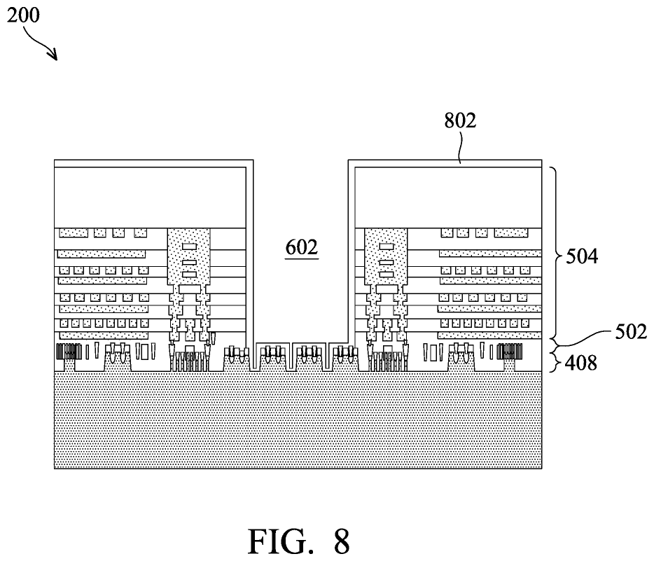

The method 100 includes block 118 where a spacer liner layer is deposited including along the sidewalls of the opening of block 114. Referring to the example of FIG. 8, a spacer liner layer 802 is deposited. The spacer liner layer 802 may be deposited by atomic layer deposition (ALD) or other suitable deposition methods. In an embodiment, the spacer liner layer 802 is an oxide such as silicon oxide. In other implementations, the spacer liner layer 802 may include a dielectric such as another oxide, silicon nitride, silicon carbon nitride, and/or other suitable materials. In an embodiment, the spacer liner layer 802 is between about 150 and 300 nanometers (nm) in thickness. In an embodiment, the spacer liner layer 802 has a thickness less than 150 nm. As illustrated in FIG. 8, the deposition of the spacer liner layer 802 may be a conformal deposition in some implementations.

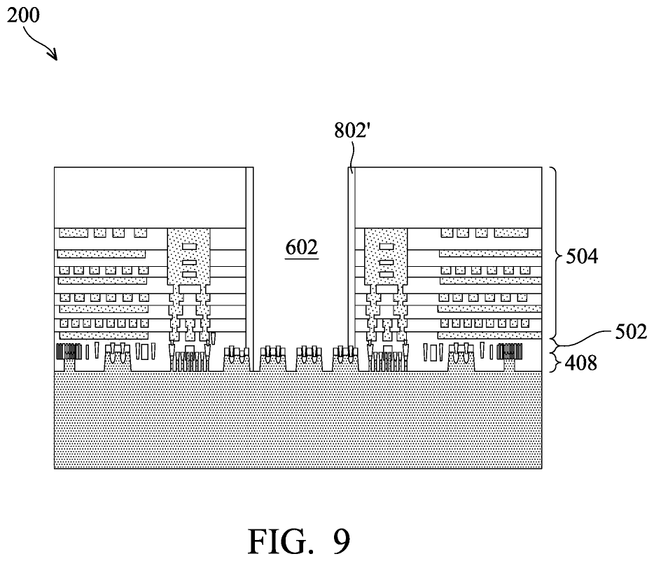

The method 100 includes block 120 where the deposited liner layer of block 118 is etched. After etching the spacer liner layer remains on the sidewalls of the via opening providing protection. Referring to the example of FIG. 9, the spacer liner layer 802 is patterned to form spacer liner layer 802′ on the sidewalls of the opening 602. In some implementations, the spacer liner layer 802′ covers a sidewall of the semiconductor structure 300 exposed by the opening 602. The etching of the spacer liner layer 802′ may be an anisotropic etch such as a dry plasma etch, a wet etch, and/or other suitable etching.

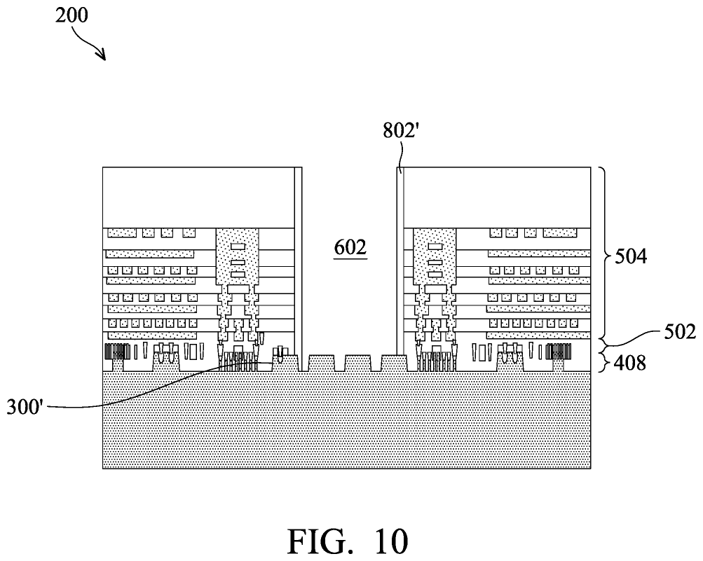

The method 100 includes block 122 where the transistor features of the through via region are removed by etching process(es). Referring to the example of FIG. 10, the gate structures 402 and source/drain regions 404 are removed. In some implementations, the etching also removes portions of the semiconductor structure 300, such as the fins 304 on the crown structure 302. Thus, the crown structure 302 may have a substantially planar top surface. The etching may be selective to the gate structures 402 and source/drain region 404 and thus, the spacer liner layer 802′ may be substantially unetched. The etching process(es) can include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. In some embodiments, a plurality of etching processes are performed.

The method 100 includes block 124 where another masking element is formed over the BEOL structures on the substrate. The another masking element may define substantially the same pattern as the masking element of block 112. Referring to the example of FIG. 11A, a masking element 1102 having an opening 1102A defining the through via location with respect to the substrate is formed over the BEOL layer 504. The masking element 1102 may be a photoresist. In some implementations, the masking element 1102 may also include a hard mask layer. In some implementations, the opening 1102A has a dimension of approximately D, as discussed above. The masking element 1102 may be patterned using suitable photolithography and etching processes. In some implementations, the masking element 1102 may be patterned using substantially the same photomask as the masking element 506. The masking layer 1102 may include photoresist, silicon oxide, silicon nitride, silicon carbide, aluminum oxide, titanium nitride, or other suitable materials. The deposited masking layer then undergoes a pre-exposure baking process, exposure to radiation reflected from or transmitted through a photomask, a post-exposure baking process, and developing process, so as to form a patterned masking layer with an opening aligning with to-be formed through via.

FIG. 11B is illustrative of a device 200′ that is substantially similar to the device 200. FIG. 11B and the device 200′ is illustrative of an opening 602 that has sidewalls defined by the ILD 502A and IMD 504A.

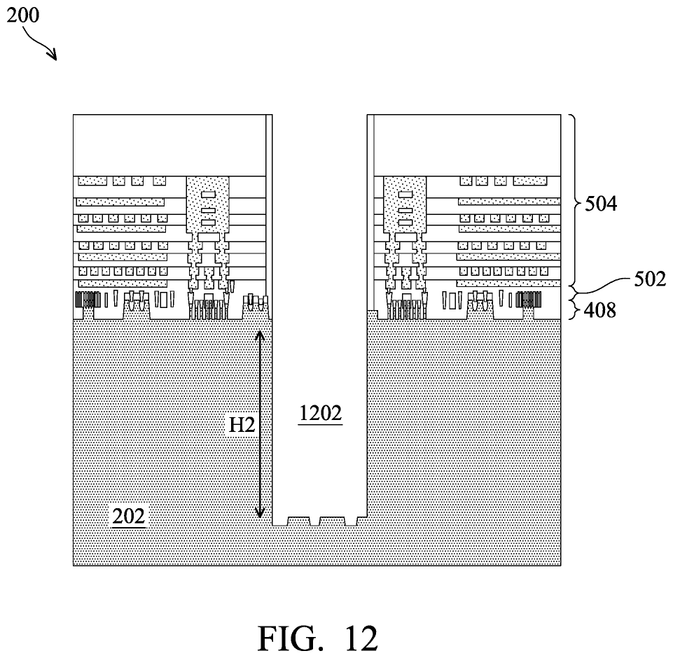

The method 100 includes block 126 where the through via opening is extended into the substrate by etching the substrate according to the pattern defined by the masking element of block 124. Referring to the example of FIG. 12, the substrate 202 of the device 200 has been etched to extend the opening 602 into the substrate forming opening 1202. It is noted that bottom of the opening 1202 is non-planar as the substrate surface before etching (FIG. 11) is also non-planar due to the presence of semiconductor structures 300. That, the bottom of the opening 1202 includes a plurality of recesses corresponding with the semiconductor structures 300. The etching may be selective to the substrate 202 (e.g., silicon) and leave the spacer liner layer 802 substantially unetched. In some implementations, the substrate is etched 25-100 μm (H2). In an embodiment, H2 is about 50 μm. The etch process may be a dry etch process (e.g., a reactive ion etching (RIE) process). In some instances, an example dry etch process may implement an oxygen-containing gas (e.g., O₂), a fluorine-containing gas (e.g., SF₆ or NF₃), a chlorine-containing gas (e.g., Cl₂ and/or BCl₃), a bromine-containing gas (e.g., HBr), an iodine-containing gas, other suitable gases and/or plasmas, combinations thereof, and/or other suitable etches. The termination of the etching may be controlled by time.

After etching the substrate 202 to form the opening 1202, an ashing process may be performed to remove the masking element 1102 from the substrate 202. The ashing process may be followed by additional wet etching/clean process. And the device 200 may be subsequently baked or annealed in a high temperature process.

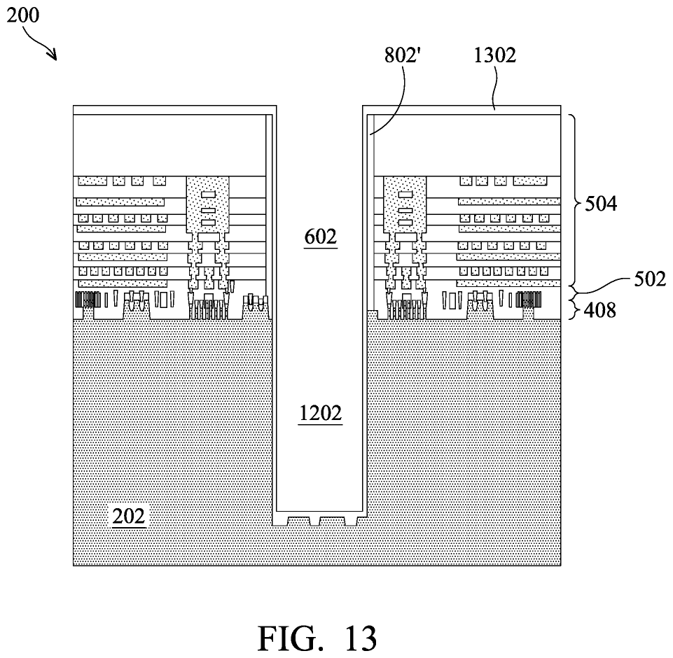

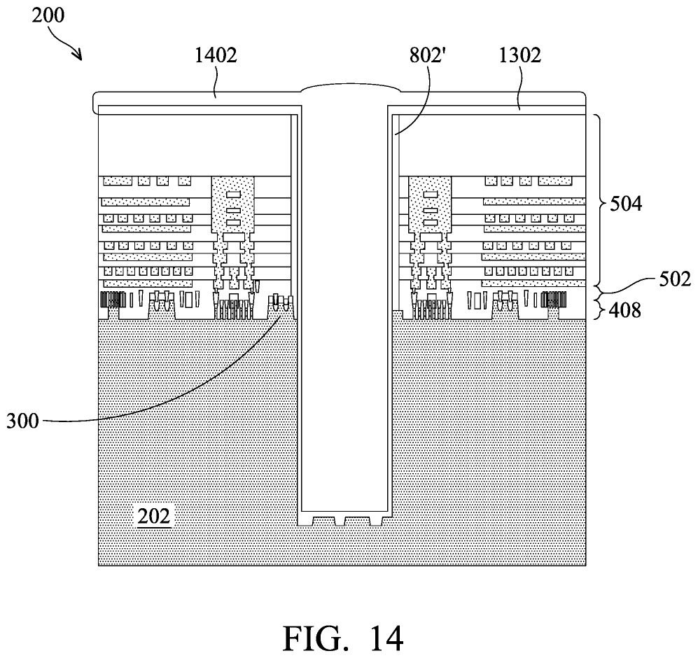

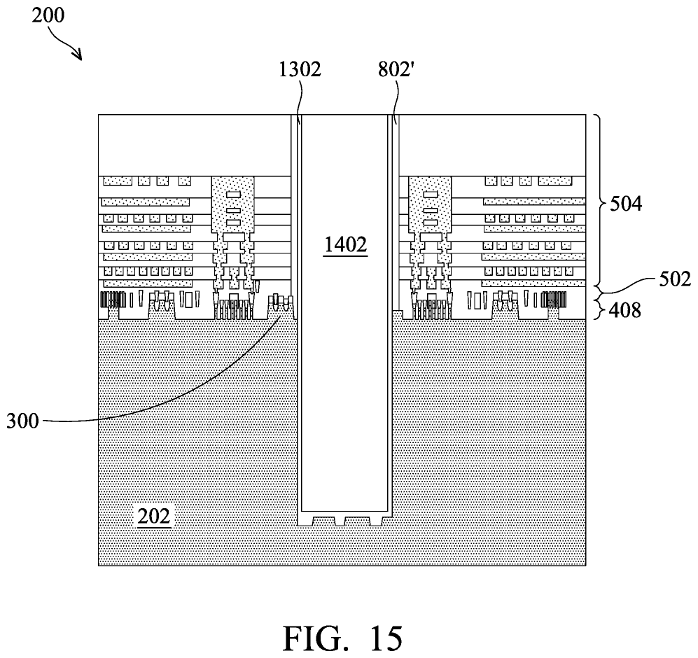

The method 100 includes block 128 where the through silicon via (TSV) is formed in the opening. In an embodiment, a liner layer is first deposited. Referring to the example of FIG. 13, a liner 1302 is formed. In an embodiment, the liner 1302 is an oxide. Over the liner layer, conductive materials are formed. In some implementations, a barrier or seed layer may be deposited on the liner 1302. And over the seed layer, a bulk metallization layer is formed. Referring to the example of FIG. 14, a seed layer and a metallization layer are deposited to form the conductive layer 1402.

In some implementations, liner 1302 is an oxide. In other implementations, the liner 1302 may include tantalum nitride (TaN), titanium nitride (TiN), tungsten nitride (WN), aluminum nitride (AlN), or combinations thereof. The liner 1302 may fill the recesses in the bottom of the opening 1202. The metal layers 1402 may include copper (Cu), aluminum (Al), cobalt (Co), copper alloy, tantalum (Ta), titanium (Ti), tungsten (W), and/or other suitable materials. To form the conductive through via 1600, the liner layer 1302 is first deposited using PVD, CVD, MOCVD, ALD, or a combination thereof as illustrated in the exemplary FIG. 11. Then, the metal fill layer 1402 is deposited using electroplating, PVD, CVD, electroless plating, or a suitable method. In one embodiment, the metal fill layer 1402 is formed using electroplating. In this embodiment, the seed layer (of layer 1402) may be deposited, using PVD or a suitable process including over surfaces of the liner layer 1302. Then the metal fill layer may be deposited over the seed layer using electroplating. In the embodiment where electroplating is used, the seed layer may include copper (Cu), titanium (Ti), or a combination thereof and the metal fill may include copper (Cu). Again, the seed layer may be considered part of the metal layer 1402.

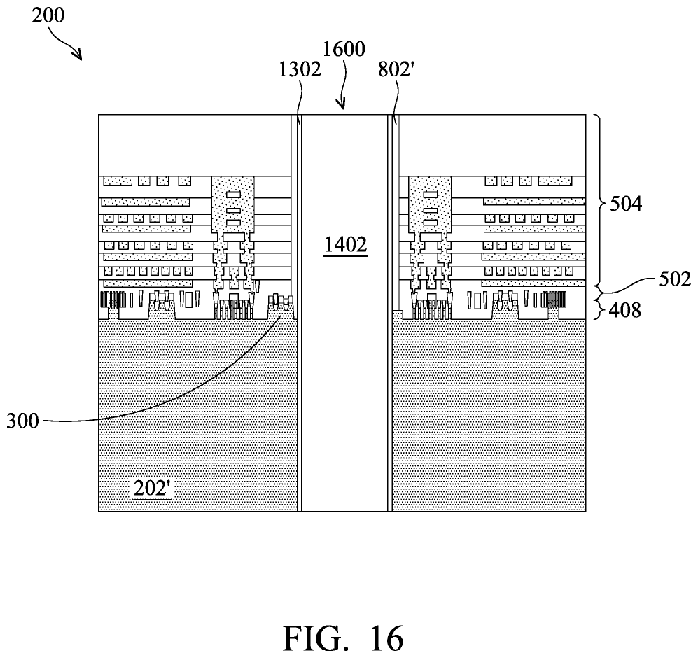

After deposition, a planarization process may be performed to remove the materials from a top surface of the device 200 to form the conductive via. The planarization process may include chemical mechanical polishing (CMP) or other suitable etching back process. Referring to the example of FIG. 15, the device 200 is planarized.

To complete the formation of the through via, the semiconductor substrate 202 is thinned, for example through chemical mechanical polishing or grinding processes, to expose a bottom surface of the via. In the example of FIG. 16, portions of the substrate 202′ are removed to form the thinned substrate 202′. The removal continues such that a bottom surface of the through via and conductive materials 1402 are exposed. That is, the formed through via 1600 now extends through the substrate 202′.

The method 100 continues to block 130 where further processing is performed. The method 100 may include forming additional conductive and/or insulative features over the substrate—frontside or backside—connected to the TSV. It is noted that some frontside processing may be performed prior to the thinning of the substrate. In the embodiment of FIGS. 17A, 17B, an insulative layer 1702A is formed on the backside of the device 200. The insulative layer may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. In an embodiment, a conductive feature or interconnect layer 1702B is also formed on the backside of the substrate connected to the through via 1600. Exemplary metal material of the interconnect layer 1702B may include copper (Cu), cobalt (Co), nickel (Ni), aluminum (Al), or a metal alloy, such as aluminum-copper alloy (Al—Cu). Additional layers such as passivation layers, bond pads, external interconnects such as solder balls, and the like may also be formed.

Thus, the method 100 and the exemplary device 200 illustrate embodiments providing a through silicon via. In some implementations, dishing is avoided as semiconductor structures or fins and associated transistor features are formed in the through via region that are subsequently removed after MEOL and BEOL features are formed.

It is noted in device 200, 200′ as illustrated in FIGS. 17A and 17B, a FEOL structure adjacent the through silicon via may be a dummy feature. In some embodiments, the dummy feature includes the semiconductor structure 300, gate structure 402, and source/drain features 404. However, no electrical connection is made to the device. The dummy feature is annotated as “A”.

It is also noted in as illustrated in FIG. 17A, a portion of the semiconductor structure 300 may remain adjacent the TSV 1600. This may be provided in embodiments where the openings, such as opening 602 has a sidewall that lands on the semiconductor structure 300. In other embodiments, portions of the gate structure 402 and/or source/drain features 404 may be maintained on a residual portion of such as semiconductor structure 300. In embodiments, no electrical connection is made to the device. The residual feature is annotated as “B.”

In one exemplary aspect, the present disclosure is directed to a method. The method includes forming a plurality of semiconductor structures extending above a substrate. And the method includes forming a plurality of metal gates over the plurality of semiconductor structures forming a multi-layer interconnect layers over the plurality of metal gate. A first etching process is performed to form a first opening extending through the MLI layers to expose a first metal gate structure of the plurality of metal gates on a first semiconductor structure of the plurality of semiconductor structures. A spacer liner layer is deposited on sidewalls of the first opening. A second etching process is performed to remove the first metal gate structure. And a third etching process is performed to remove the first semiconductor structure and extend the first opening into the substrate to form an extended opening.

In a further embodiment, the method includes filling the extended opening with conductive material. An in some implementations, the method includes thinning the substrate to expose a bottom surface of the filled extended opening to form a through silicon via (TSV). In an embodiment, forming the plurality of semiconductor structures includes forming the first semiconductor structure as a crown structure having a plurality of fins extending from the crown structure. In an embodiment, forming the multi-layer interconnect layers over the plurality of metal gates includes forming a contact structure to a second metal gate structure of the plurality of metal gates and forming a first metallization layer over the second metal gate structure and connected to the contact structure. In an embodiment, depositing the spacer liner layer on sidewalls of the first opening includes: conformally depositing an oxide layer; and etching the oxide layer to expose the first metal gate structure.

In an embodiment, performing the second etching process to remove the first metal gate structure etches a portion of the first semiconductor structure. And in a further implementation, the portion of the first semiconductor structure is fins extending above a crown structure. In an embodiment, the extended opening has a non-planar bottom surface, the non-planar bottom surface having a plurality of recesses. And in some implementations, the method includes depositing a dielectric barrier layer in the extended opening filling the plurality of recesses.

In another exemplary aspect, the present disclosure is directed to an embodiment of method of forming a semiconductor device. The method includes forming front-end-of-the-line (FEOL) layer including a plurality of transistor features on a substrate; forming middle-end-of-the-line (MEOL) layer including a plurality of contact features over the FEOL layer; and forming back-end-of-the-line (BEOL) layer including a plurality of metal lines and vias over the MEOL layer. An opening is etched through the BEOL layer and the MEOL layer. The opening is defined by a first masking element and has a bottom surface defined by the substrate. A spacer liner layer is deposited on sidewalls of the opening. A second masking element is provided over the BEOL layer and the method includes etching the substrate in a region defined by the second masking element to extend the opening into the substrate. The extended opening is filled with conductive material.

In a further embodiment, the masking element before depositing the spacer liner layer. In an embodiment, a dummy transistor feature is exposed at the bottom surface; and the spacer liner layer is deposited on the dummy transistor feature. In further embodiment, after forming the opening and prior to providing the second masking element and etching the substrate, performing another etching process to remove the dummy transistor feature. In an embodiment, the dummy transistor feature is a gate structure disposed on a fin. In an embodiment the method also includes thinning the substrate to expose a bottom surface of the filled extended opening.

In yet another exemplary aspect, the present disclosure is directed to a semiconductor structure. The structure includes a substrate; a plurality of semiconductor structures extending above the substrate; a multi-layer interconnect (MLI) disposed over the substrate and the plurality of semiconductor structures; and a through substrate via extending vertically through the substrate and the MLI. The plurality of semiconductor structures includes a first semiconductor structure having a first metal gate disposed thereover and a second semiconductor structure having a second metal gate disposed thereover. The MLI is connected to the first metal gate and the MLI is not electrically connected to the second metal gate. A spacer liner layer is formed on a sidewall of the second semiconductor structure and is disposed between the sidewall and a first sidewall of the through substrate via.

In a further embodiment the structure includes a third semiconductor structure is adjacent a second sidewall of the through substrate via. The third semiconductor structure extends above the substrate, and the spacer liner layer interfaces a top surface of the third semiconductor structure. In an embodiment, the second semiconductor structure is a crown structure having a plurality of fins extending from a base portion. And in a further embodiment, a sidewall extends from a top of a fin of the plurality of fins, along the fin and along the base portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of semiconductor device fabrication, the method comprising:
forming a plurality of semiconductor structures extending above a substrate;
forming a plurality of metal gates over the plurality of semiconductor structures;
forming a multi-layer interconnect layers over the plurality of metal gate;
performing a first etching process to form a first opening extending through the MLI layers to expose a first metal gate structure of the plurality of metal gates on a first semiconductor structure of the plurality of semiconductor structures;
depositing a spacer liner layer on sidewalls of the first opening;
performing a second etching process to remove the first metal gate structure; and
performing a third etching removing the first semiconductor structure and extending the first opening into the substrate to form an extended opening.

2. The method of semiconductor device fabrication of claim 1, further comprising:
filling the extended opening with conductive material.

3. The method of semiconductor device fabrication of claim 2, further comprising:
thinning the substrate to expose a bottom surface of the filled extended opening to form a through silicon via (TSV).

4. The method of semiconductor device fabrication of claim 1, wherein the forming the plurality of semiconductor structures includes forming the first semiconductor structure as a crown structure having a plurality of fins extending from the crown structure.

5. The method of semiconductor device fabrication of claim 1, wherein forming the multi-layer interconnect layers over the plurality of metal gates includes forming a contact structure to a second metal gate structure of the plurality of metal gates and forming a first metallization layer over the second metal gate structure and connected to the contact structure.

6. The method of semiconductor device fabrication of claim 1, wherein depositing the spacer liner layer on sidewalls of the first opening includes:
conformally depositing an oxide layer; and
etching the oxide layer to expose the first metal gate structure.

7. The method of semiconductor device fabrication of claim 1, wherein performing the second etching process to remove the first metal gate structure etches a portion of the first semiconductor structure.

8. The method of semiconductor device fabrication of claim 7, wherein the portion of the first semiconductor structure is fins extending above a crown structure.

9. The method of semiconductor device fabrication of claim 1, wherein the extended opening has a non-planar bottom surface, the non-planar bottom surface having a plurality of recesses.

10. The method of semiconductor device fabrication of claim 9, further comprising:
depositing a dielectric barrier layer in the extended opening filling the plurality of recesses.

11. A method of forming a semiconductor device, comprising:
forming front-end-of-the-line (FEOL) layer including a plurality of transistor features on a substrate;
forming middle-end-of-the-line (MEOL) layer including a plurality of contact features over the FEOL layer;
forming back-end-of-the-line (BEOL) layer including a plurality of metal lines and vias over the MEOL layer;
etching an opening through the BEOL layer and the MEOL layer, wherein the opening is defined by a first masking element, wherein the opening has a bottom surface defined by the substrate;
depositing a spacer liner layer on sidewalls of the opening;
providing a second masking element over the BEOL layer and etching the substrate in a region defined by the second masking element to extend the opening into the substrate; and
filling the extended opening with conductive material.

12. The method of claim 11, further comprising: removing the first masking element before depositing the spacer liner layer.

13. The method of claim 11, wherein a dummy transistor feature is exposed at the bottom surface; and the spacer liner layer is deposited on the dummy transistor feature.

14. The method of claim 13, further comprising:
after forming the opening and prior to providing the second masking element and etching the substrate, performing another etching process to remove the dummy transistor feature.

15. The method of claim 14, wherein the dummy transistor feature is a gate structure disposed on a fin.

16. The method of claim 11, further comprising:
thinning the substrate to expose a bottom surface of the filled extended opening.

17. A semiconductor structure, comprising:
a substrate;
a plurality of semiconductor structures extending above the substrate, wherein the plurality of semiconductor structures includes a first semiconductor structure having a first metal gate disposed thereover and a second semiconductor structure having a second metal gate disposed thereover;
a multi-layer interconnect (MLI) disposed over the substrate and the plurality of semiconductor structures, wherein the MLI is connected to the first metal gate and the MLI is not electrically connected to the second metal gate; and
a through substrate via extending vertically through the substrate and the MLI, wherein a spacer liner layer is formed on a sidewall of the second semiconductor structure and is disposed between the sidewall and a first sidewall of the through substrate via.

18. The semiconductor structure of claim 17, wherein a third semiconductor structure is adjacent a second sidewall of the through substrate via, wherein the third semiconductor structure extends above the substrate, and the spacer liner layer interfaces a top surface of the third semiconductor structure.

19. The semiconductor structure of claim 17, wherein the second semiconductor structure is a crown structure having a plurality of fins extending from a base portion.

20. The semiconductor structure of claim 19, wherein the sidewall extends from a top of a fin of the plurality of fins, along the fin and along the base portion.
